(19) United States
(12) Patent Application Publication
(10) Pub. No.: US 2026/0293078 A1
(43) Pub. Date: Sep. 24, 2026

(54) MEMORY DEVICE WITH IMPROVED SENSING MARGIN AND LEAKAGE IMMUNITY

(71) Applicant: Synopsys, Inc., Sunnyvale, CA (US)

(72) Inventors: Salvatore Maria Amoroso, Hamilton (GB); Plamen Asenov Asenov, Glasgow (GB); Meng-Hsuan Ke, Chupei (TW); Ko-Hsin Lee, Zhubei City (TW); Xi-Wei Lin, Fremont, CA (US)

(21) Appl. No.: 19/085,257

(22) Filed: Mar. 20, 2025

(51) Int. Cl. H10B 12/00; H10D 62/10; H10D 62/13; H10D 64/23

(52) U.S. Cl. CPC H10B 12/00; H10B 12/01; H10D 62/102; H10D 62/151; H10D 64/251; G11C 2211/4068

(57) ABSTRACT

A memory cell includes a capacitor, a first transistor, and a second transistor. The capacitor has a first plate and a second plate adjacent to the first plate. The first transistor has a channel, a gate terminal, a source terminal, and a drain terminal, wherein the gate terminal surrounds the channel, one side of the channel is connected to the source terminal, another side of the channel is connected to the drain terminal. The second transistor has a channel, a gate terminal, a source terminal and a drain terminal, wherein the gate terminal surrounds the channel, one side of the channel is connected to the source terminal, another side of the channel is connected to the drain terminal. The drain terminal of the first transistor is connected to the first plate of the capacitor. The gate terminal of the first transistor and the gate terminal of the second transistor are connected together.

### TECHNICAL FIELD

The present disclosure relates to three-dimensional dynamic random access memory (3D-DRAM) devices and methods of manufacturing such devices.

### BACKGROUND

DRAM is a type of volatile memory that stores each bit of data in a separate capacitor within an integrated circuit. In some DRAM design, a memory cell includes one transistor and one capacitor.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 depicts an example memory cell, according to an embodiment of the present disclosure.

FIG. 2 depicts a schematic of a memory cell, according to an embodiment of the present disclosure.

FIGS. 3a through 3o depict an example process for building a three-dimensional memory device, according to an embodiment of the present disclosure.

FIG. 4 depicts schematics for simulated one-transistor-one-capacitor (1T1C) and two-transistor-one-capacitor (2T1C) memory cells, according to an embodiment of the present disclosure.

FIG. 5 depicts a comparison between a 2T1C memory cell and a 1T1C memory cell under ideal conditions, according to an embodiment of the present disclosure.

FIG. 6 depicts a comparison between a 2T1C memory cell and a 1T1C memory cell under a first operating condition, according to an embodiment of the present disclosure.

FIG. 7 depicts a flowchart of various processes used during the design and manufacture of an integrated circuit, according to an embodiment of the present disclosure.

FIG. 8 depicts a diagram of an example computer system in which embodiments of the present disclosure may operate.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

In some DRAM designs, a memory cell includes one transistor and one capacitor (1T1C). The capacitor can be either charged or discharged to store one bit of information. A charged capacitor represents a logic “1” value while a discharged capacitor represents a logic “0” value. However, because capacitors leak charge, the information eventually becomes incorrect unless the capacitor charge is periodically refreshed. As semiconductor devices continue to scale down in size, DRAM manufacturers have explored 3D architectures to achieve higher memory density while maintaining acceptable performance characteristics. In some 3D DRAM designs, memory cells are stacked vertically to increase the number of bits that can be stored in a given area. However, such 3D DRAM designs face several challenges including reduced sensing margins, increased leakage currents, floating body effects, and vulnerability to disturbance effects such as row hammer attacks. These challenges can lead to degraded performance, reduced reliability, and increased power consumption due to more frequent refresh operations.

Aspects of the present disclosure relate to a three-dimensional (3D) memory device architecture and methods of fabrication that address the challenges of other 3D DRAM designs. The systems and methods disclosed herein provide improved sensing margin and enhanced immunity to leakage effects through a two-transistor-one-capacitor (2T1C) memory cell configuration.

In some aspects, a memory cell includes a storage capacitor having a first plate and a second plate separated by a dielectric material, and two transistors connected to opposite plates of the capacitor. The first transistor has its drain terminal electrically connected to the first plate of the storage capacitor and its source terminal connected to a first bitline, while the second transistor has its drain terminal electrically connected to the second plate of the storage capacitor and its source terminal connected to a second bitline. The gate terminals of both transistors are connected to a common wordline, with the first and second bitlines configured to carry complementary voltage levels during memory operations. This configuration provides a three-fold improvement in sensing margin compared to other designs and maintains robust operation even in the presence of leakage currents.

In some aspects, a three-dimensional memory device includes multiple memory cells layered together to form a stack, with bitlines positioned along opposite sides of the stack and a wordline connecting to each layer. This vertical integration provides high-density memory while maintaining reliable operation through improved immunity to floating body effects and row-hammer attacks.

In some aspects, methods of fabricating a three-dimensional memory devices are provided, including techniques for forming the vertically stacked transistor regions, capacitor regions, and their interconnections. The fabrication methods provide practical implementation of the improved memory cell architecture while maintaining compatibility with other semiconductor processing techniques.

Advantages of the disclosed three-dimensional memory device include, for example, improved sensing margin, retention and immunity to floating body and row-hammer attacks. The three-dimensional memory device includes vertically stacked 2T1C cells. In a memory cell, a second transistor is fabricated next to the capacitor, to replace what in the 1T1C configuration was a common ground metal plate. The two transistors connected to the opposite sides of the capacitor share, the same wordline connection and are driven by two separate bitlines. The wordline is used to activate the bit cells in a row of memory cells based on a combination of address bits by turning on the transistors connected to the wordline. This allows the data stored in the capacitor of the memory cell to be accesses (read/write) via the bitline. Technical benefits of this approach are, for example, the following: increased sensing margin, up to three times (3X) as shown by our SPICE simulation; robustness to leakage and floating body for 3D-DRAM, as confirmed by SPICE simulation methodology; faster sensing; the memory cell may need less capacitance because of the larger sensing signal; multiple neighbor arrays can be addressed simultaneously because now 1 bitline is not used as a reference (contrary to a 1T1C approach); and the 2T1C design can save periphery area because the sense amplifier can now be smaller, due to the larger differential signal.

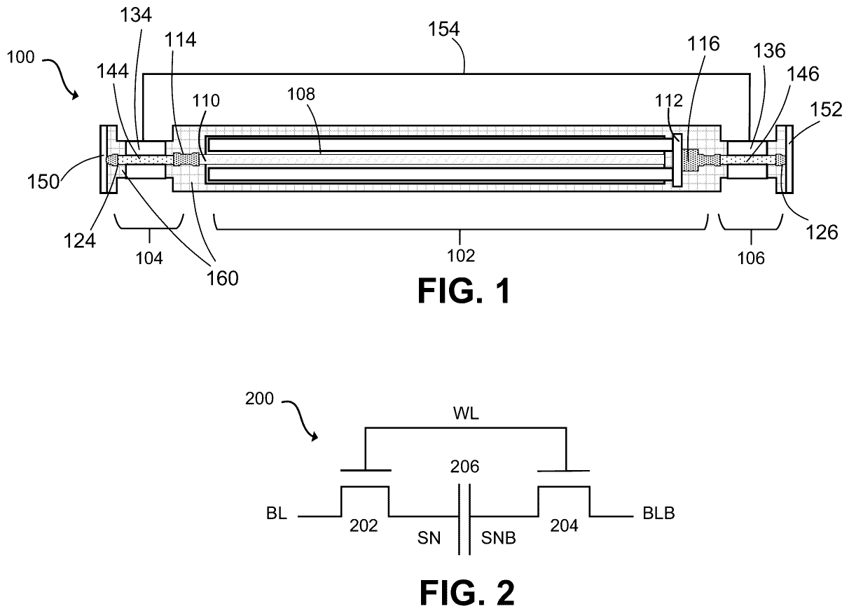

Referring now to FIG. 1, it illustrates an example memory cell 100 in accordance with an embodiment. The memory cell 100 includes a storage capacitor 102, a first transistor 104, and a second transistor 106. The storage capacitor 102 has a first plate 110 and a second plate 112 separated by a dielectric material 108.

The first transistor 104 has a drain terminal 114, a source terminal 124, a gate terminal 134, and a channel 144. The drain terminal 114 is electrically connected to the first plate 110 of the storage capacitor 102 and the source terminal 124 is electrically connected to a first bitline 150.

The channel 144 is a region of semiconductor material that forms the critical conductive pathway between the source and drain terminals. When the transistor is in operation, the channel acts as a controllable bridge that can either permit or block the flow of electrical current based on the voltage applied to the gate terminal. The gate terminal surrounds the channel, allowing for electrostatic control over the channel's conductivity. This arrangement provides the gate voltage to efficiently modulate the electrical characteristics of the channel by attracting or repelling charge carriers throughout the cross-section of the channel.

The second transistor 106 has a drain terminal 116, a source terminal 126, a gate terminal 136, and a channel 146. The drain terminal 116 is electrically connected to the second plate 112 of the storage capacitor 102 and the source terminal 126 is electrically connected to a second bitline 152. The gate terminals 143, 136 of the first and second transistors 104, 106 are electrically connected to a common wordline 154. The first and second bitlines 150, 152 carry complementary voltage levels during memory operations. In some embodiments, the first transistor and second transistor and the storage capacitor are separated by isolation regions.

Isolation regions 160 physically and electrically separate different components of the memory cell (the first transistor, second transistor, and capacitor) from each other. Isolation regions 160 prevent unwanted electrical interactions between adjacent components, reducing interference and cross-talk. The isolation regions can be filled with a dielectric material.

In operation, the storage capacitor 102 maintains a non-zero voltage differential between the first and second plates in response to charge leakage through one of the first or second transistors. The first plate stores a first voltage level and the second plate stores a second voltage level different from the first voltage level. The memory cell maintains a non-zero differential between the first plate and the second plate when charge leakage through one of the first transistor or second transistor causes a change in voltage level induced by capacitive coupling between the plates. The capacitive coupling of the first plate and second plate provides protection against row-hammer attacks. The charge leakage can include one of: a source-to-drain leakage current through a channel of one of the first or second transistors; a junction leakage current due to defects in one of the first or second transistors; a leakage current due to floating body effects in one of the first or second transistors; and a gate-induced drain leakage current in one of the first transistor or second transistor.

According to some embodiments, capacitive coupling between the first plate and the second plate of the storage capacitor causes voltages at the first plate and the second plate to shift in a coordinated manner in response to charge leakage through one of the first or second transistors. By way of example, a Coordinated manner may include having the voltages at both plates of the storage capacitor change together in a related, predictable pattern when charge leakage occurs. For example, when charge leakage occurs through one of the transistors (causing a voltage change at its connected plate), the capacitive coupling between the two plates causes the voltage at the opposite plate to also change in a proportional and/or predictable way. This coordinated voltage movement means that while the absolute voltage values at both plates may change due to leakage, the relative voltage differential between them is largely preserved. For example, if leakage through the first transistor causes the voltage at the first plate to decrease by a certain amount, the capacitive coupling will cause the voltage at the second plate to also decrease, but by a proportionally related amount. This proportional relationship helps maintain the stored information (represented by the voltage differential) even as some charge is lost through leakage. This coordinated voltage response is one of the advantages of the two-transistor-one-capacitor design over traditional one-transistor designs, as it preserves the sensing margin despite leakage effects.

Unlike 1T1C cells where leakage directly diminishes the stored charge and sensing margin, the capacitive coupling provides that the voltage differential remains largely intact despite leakage through a single transistor. These features can provide resistance to various leakage mechanisms without requiring additional circuitry or power consumption.

FIG. 2 illustrates an example schematic of the memory cell 200 in accordance with an embodiment. The memory cell 200 includes a storage capacitor 206 with one hold transistor 202 connected in series to one of the capacitor's plates and a second hold transistor 204 connected in series to the other capacitor's plate, as schematically represented in FIG. 2. The gate terminals of the transistors 202 and 204 are both connected to the same wordline (WL). The drain terminals of the transistors 202 and 204 are connected to the two opposite plates of the capacitor 206. The source terminals of the transistors 202 and 204 are connected to two separate Bitlines (BLs), BL and BLB, which can carry complementary voltage information during DRAM operations (e.g. if BL is charged at 1V then BLB will be charged at 0V). The same is true for the stored information on the two sides of the capacitor 206 (e.g., if SN is storing 1V then SNB will be storing 0V).

By having a second dedicated BL, multiple neighbor arrays can be addressed simultaneously because the neighbor's bitline is not used as a reference (contrary to a 1T1C approach). On the other hand, having a second dedicated bitline can introduce an area/power penalty and possibly a more complicated routing.

In some embodiments, the presence of a second transistor may result in an area penalty. Moreover, part of the area lost in the cell area can be recovered in the logic area, because the large differential signal offered by a 2T1C configuration (e.g., demonstrated by SPICE simulation methodology) can enable the adoption of more scaled sense amplifier circuitry.

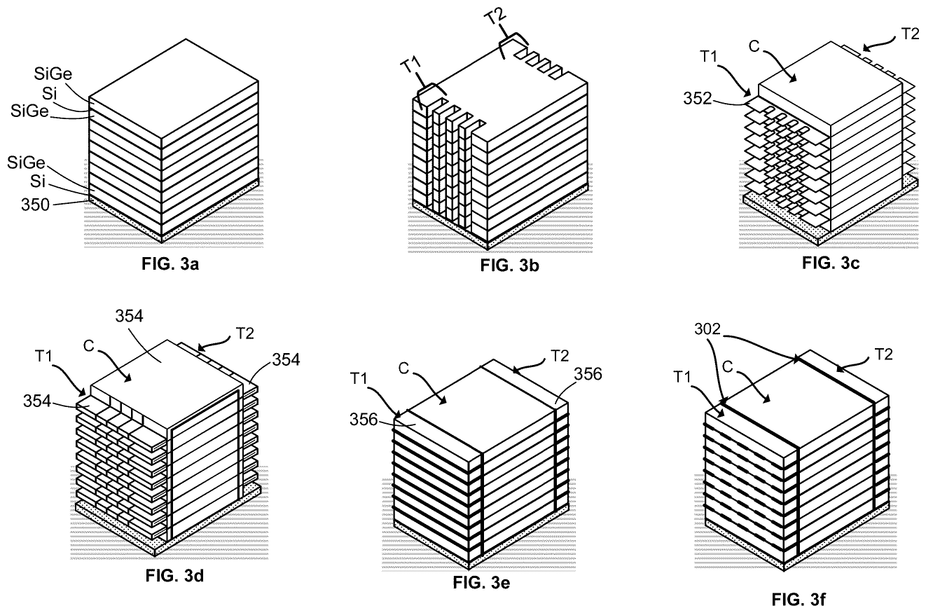

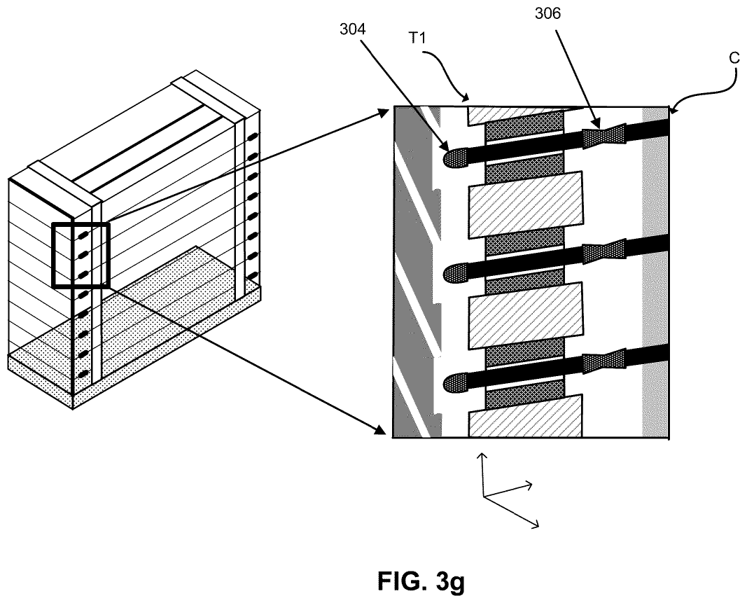

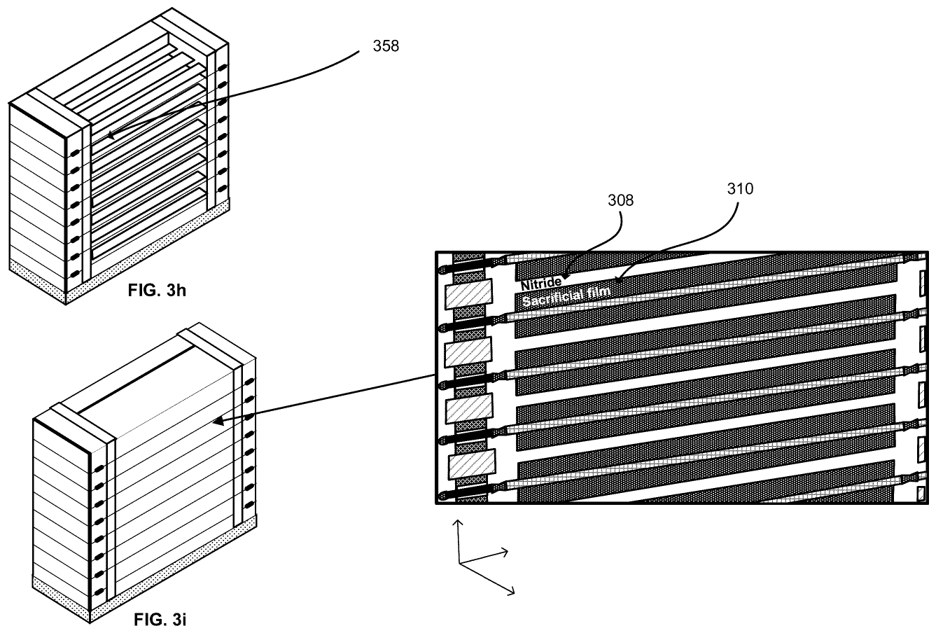

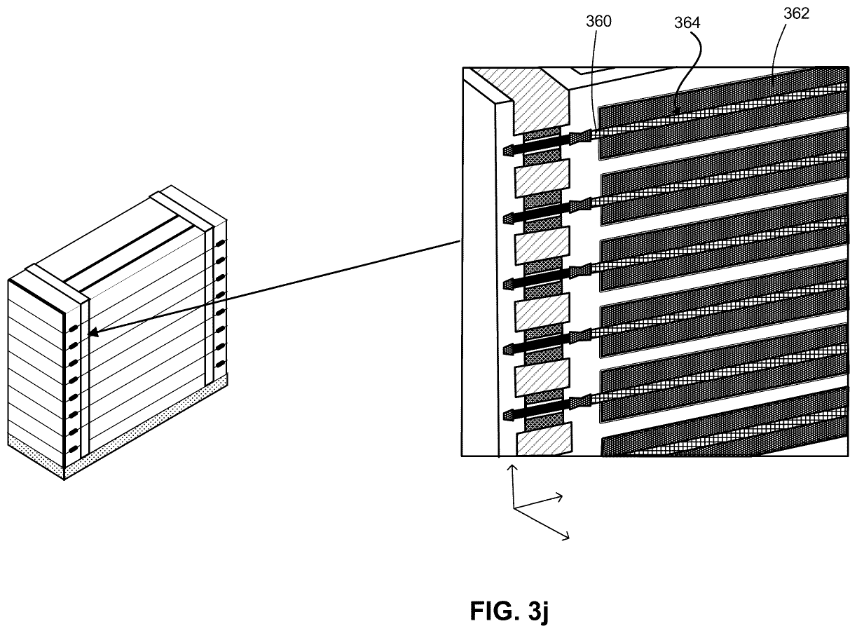

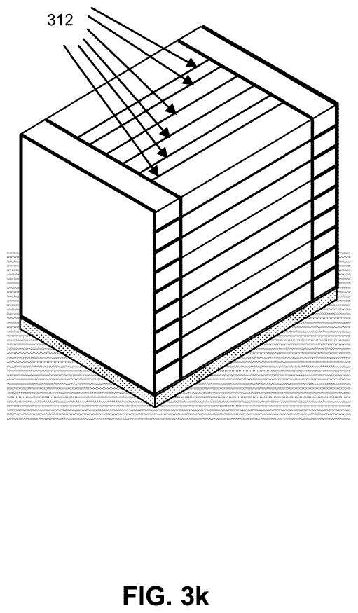

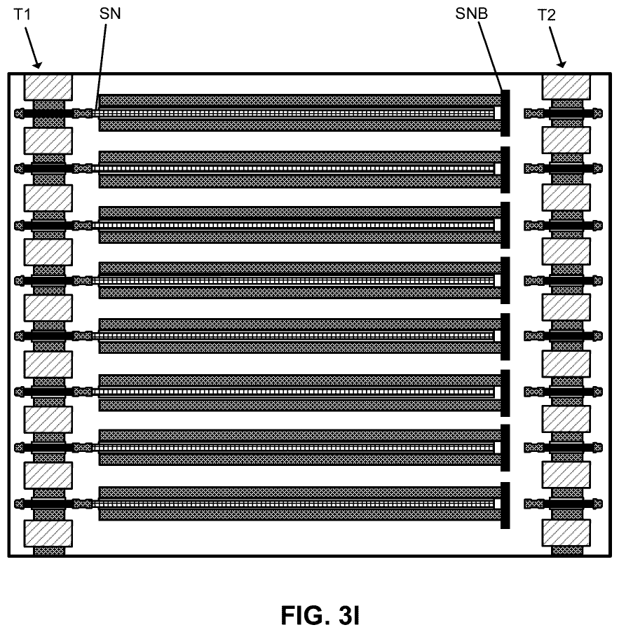

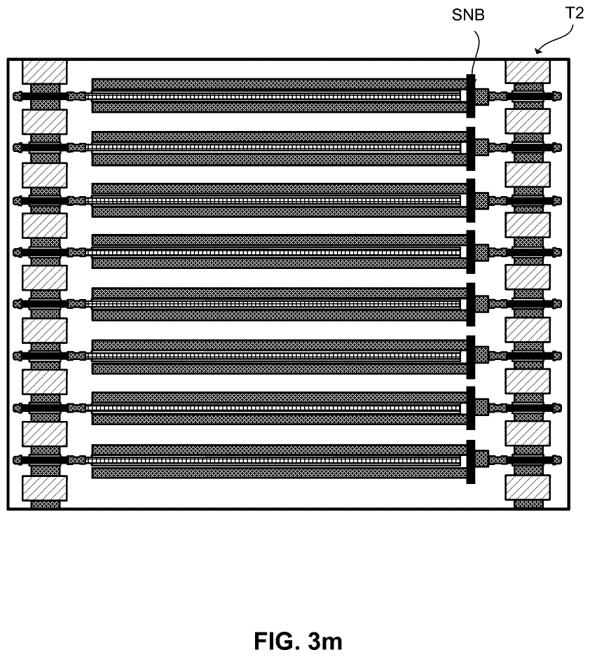

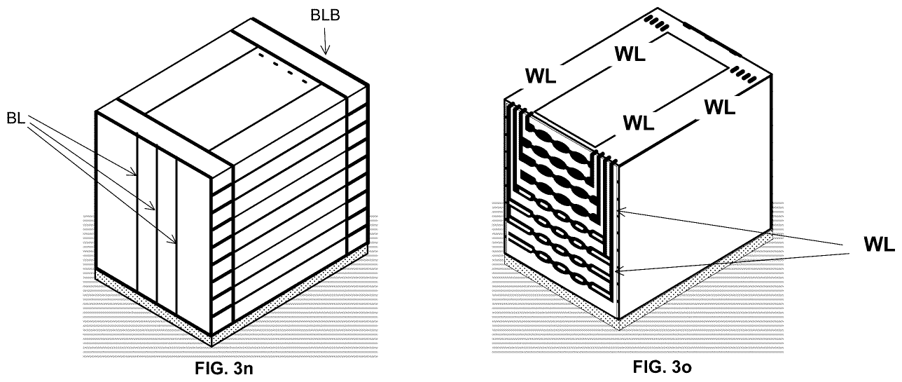

FIGS. 3a-3o depicts various steps of a process for building a three-dimensional memory device. The process includes providing alternating layers of a first semiconductor material and a second semiconductor material. FIG. 3a shows alternating layers of a first semiconductor material and a second semiconductor material. The first semiconductor material may include silicon (Si) and the second semiconductor material may include silicon-germanium (SiGe). The bottom layer 350 is a foundational layer that provides structural integrity and mechanical stability for the entire memory device architecture. The bottom layer can be made of Si. The support layer serves as the base upon which all subsequent alternating semiconductor layers are deposited and processed during fabrication. These semiconductor materials (e.g., Si and SiGe) are vertically stacked on top of each other in alternating layers. The alternating layers serve as the foundation for subsequent formation of the transistor regions and capacitor regions of the memory device. In some embodiments, each layer has a thickness in the range of 10 to 100 nanometers. The stack can include between 10 and 100 alternating layers. The alternating layers can be deposited using molecular beam epitaxy to achieve high-quality crystalline semiconductor layers with low defectivity, avoiding amorphous or poly-crystalline structures that would be unsuitable for the device's channel regions.

The process further includes defining first and second transistor regions in the alternating layers of the first and second semiconductor materials. Each of the first and second transistor regions are defined on opposite sides of the alternating layers. In FIG. 3b, a nitride hard mask is applied to the stack to define first and second transistor regions (T1, T2) in the alternating layers of while protecting the capacitor region. In some embodiments, the thickness of the nitride hard mask is selected based on the technology node requirements and the specifications of the lithographic scanner being used in the fabrication process. Each of the first and second transistor regions are defined on opposite sides of the alternating layers. The hard mask pattern defines two separate transistor regions that will be positioned on opposite sides of the area reserved for the capacitor region. As explained in the following paragraphs, the defined transistor regions will ultimately form the first and second transistors of the 2T1C memory cell configuration, where each transistor will be connected to opposite plates of the storage capacitor.

The process further includes forming a gate on each layer of the first and second transistor regions. For example, a respective gate is formed by removing the second semiconductor material from each of the first and second transistor regions to expose the first semiconductor material and forming the gate on the exposed first semiconductor material. In FIG. 3c, the second semiconductor material is removed from each of the first and second transistor regions to expose the first semiconductor material. A gate is formed on the exposed first semiconductor material. The second semiconductor material (e.g., silicon-germanium) is selectively removed from the transistor regions using a etch process with major lateral direction to expose the first semiconductor material (e.g., silicon) surfaces, while the capacitor region remains protected by the hard mask. Following the selective removal, a silicon dioxide gate oxide layer 352, having a thickness of, for example, approximately 5 nanometers, may be deposited on the exposed silicon surfaces. The selective removal of silicon-germanium and formation of gate oxide can occur, while the capacitor region remains protected.

In FIG. 3d, a conductive metal gate 354 is formed in both the first and second transistor regions (T1, T2) through multiple deposition and isotropic etching cycles. A metal gate 354 can also be formed on top of the capacitor region C. The metal gate formation process includes several deposition and isotropic etching loops using tungsten as the conductive material to provide a suitable wordline connection integrity. The metal gate has a thickness of approximately 10 nanometers (nm), which is self-aligned with the spacer height. The specific metal material for the gate is selected and engineered to achieve the desired work function, with tungsten being used in a preferred embodiment. The process parameters for the deposition and etching cycles are optimized based on the specific fabrication tools and recipes being employed.

The process further includes filling each layer of the first and second transistor regions with dielectric material, the dielectric material 356 being deposited on at least a portion of the conductive material. In FIG. 3e, a dielectric material is deposited to fill each layer of the first and second transistor regions (T1, T2). Any metal gate can also be removed from the capacitor region C. In some embodiments, a specific dielectric material is engineered to minimize capacitive interference between metal layers while providing structural integrity. The dielectric material is deposited on at least a portion of the conductive metal gate in a single deposition step, completing the formation of the vertical series of transistors in both the right and left regions while the capacitor region remains protected. In some embodiments, the transistors in these regions are gate-all-around (GAA), whose characteristics are controlled by several parameters: the metal gate work-function, gate oxide property, and channel doping determine the threshold voltage (VT); the source/channel and drain/channel doping profiles and spacer thickness control the leakage current; and these doping profiles also affect the ON-regime current of the transistor, creating a trade-off between leakage and write/read performance.

The process further includes forming a capacitor region between each of the first and second transistor regions and forming isolation regions between each of the first and second transistor regions and the capacitor region. In forming the isolation regions, the process includes forming isolation regions between different capacitor rows after forming the capacitor film and filling the isolation regions with a dielectric material.

In FIG. 3f, a lithography patterning is applied to define isolation (or spacer) regions 302 that physically separate the transistor regions (T1, T2) from the capacitor region (C). In some embodiments, the process uses suitable lithography-patterning and etching steps. An etching process is performed to create the physical separation between the transistor regions and the capacitor region. The spacer width may be controlled to provide both a suitable connection between transistors and capacitors (possibly needing narrow spacing) while remaining achievable by high aspect ratio etching (possibly needing wider spacing). A minimum spacer length of 10-20 nanometers (nms) is maintained to minimize the impact of the gate electric field on the storage node junction, as excessive gate electric field in this junction region would result in increased leakage and poor retention characteristics. In some embodiments, the spacing is substantially identical at both the top and bottom of the structure.

In FIG. 3g, a silicon-based epitaxial growth process is used to grow source and drain regions 304 and 306 of each transistor in the first transistor region T1. The source and drain regions 304 and 306 will connect the active transistor channel to the bitline and the storage capacitors. The epitaxially grown regions is doped to provide good electrical conductivity between the transistors and bitlines, and between the transistors and storage nodes, thereby enabling a suitable read/write performance. In some embodiments, the doping profile is designed to decrease under the isolation region to create a less abrupt transition between the N-doped regions and the P-doped channel, as an abrupt junction could negatively impact leakage and retention characteristics. The process creates physical connectivity between the semiconductor epitaxial drain regions of both transistors and the metal plates of the capacitor simultaneously in a single step. Following the epitaxial growth, a nitride dielectric film is deposited to complete the isolation between the transistor and capacitor regions.

In FIG. 3h, the transistor regions are formed with their respective drain terminals configured for electrical connection to the storage capacitor plates and their source terminals configured for electrical connection to the bitlines. The process forms the capacitor region, beginning with the transformation of the silicon in the capacitor region into titanium silicide (TiSi) 358. The process is designed to convert all of the available silicon in the capacitor region into titanium silicide, which had been protected during the previous processing steps.

The process further includes forming the capacitor region by forming a sacrificial film in the capacitor region and forming a capacitor film in the capacitor region after removing the sacrificial film. The capacitor film includes a first plate and a second plate separated by a dielectric material. In FIG. 3i, a sacrificial film 310 is deposited using an isotropic deposition process in the capacitor region. Following the sacrificial film deposition, nitride 308 is deposited to fill the gaps in the structure. In some embodiments, no special interface treatment is provided between the sacrificial film and nitride depositions, as the sacrificial film will be completely removed in subsequent steps to form the capacitor film structure.

As shown in FIG. 3j, the sacrificial film is removed through selective etching to create space for the capacitor film structure. Following the removal of the sacrificial film, the capacitor film is formed in the space previously occupied by the sacrificial film. The capacitor film structure includes a first plate 360 and a second plate 362 separated by a dielectric material 364, where the first plate will be electrically connected to the drain of the first transistor and the second plate will be electrically connected to the drain of the second transistor. This configuration provides the 2T1C cell's improved sensing margin and enhanced immunity to floating body and row-hammer attacks, as both plates of the capacitor will be actively controlled through their respective transistors. The remaining nitride continues to fill the gaps in the structure, providing isolation.

In FIG. 3k, isolation regions 312 are formed to separate different capacitor rows. The isolation regions are then filled with a dielectric material. The dielectric material provides complete isolation between the capacitor rows. Isolation prevents electrical interference between adjacent capacitor rows in the memory array, enabling each 2T1C memory cell to maintain its stored charge independently of neighboring cells.

The process further includes establishing electrical connections between the transistor regions and their respective capacitor regions. The first transistor regions are connected to a first end of the capacitor region, and the second transistor regions are connected to a second end of the capacitor region. To connect the first transistor regions with the first end of the capacitor region, first portions of the dielectric material are selectively etched to expose the first end of the capacitor region. A first region is then epitaxially grown in these etched first portions of the dielectric material, establishing an electrical connection between the drain region of each first transistor region and the exposed first end of the capacitor region. To connect the second transistor regions with the second end of the capacitor region, second portions of the dielectric material are selectively etched to expose the second end of the capacitor region. A second region is then epitaxially grown in these etched second portions of the dielectric material, establishing the capacitor electrical end and the following is connecting to a corresponding transistor in the second transistor region (T2). These epitaxially grown regions provide a suitable electrical connection between the transistors and their respective capacitor plates in the 2T1C memory cell structure.

FIG. 3l shows that the titanium silicide material from the capacitor side creates a connection point (the SN node) for a transistor in the first transistor region (T1) through epitaxy material. Similarly, the titanium nitride can create a connection point for the second transistor region (T2) through epitaxy material.

In FIG. 3m, epitaxial growth processes are performed to establish the electrical connections between the SNB nodes and the second transistors in the transistor region (T2). These epitaxial connections follow the same process parameters to provide consistent electrical characteristics for both transistor-to-capacitor connections in the 2T1C memory cell structure.

The process further includes forming bitlines, such as first bitline connected to a source region in the first transistor region, and a second bitline connected to a source region in the second transistor region. In FIG. 3n, vertical bitlines BL and BLB are formed using tungsten as the conductive material. The formation process includes lithography patterning, etching, and tungsten deposition steps. The height of the vertical bitlines is determined by the number of stacked memory cells in the structure. The bitlines are arranged vertically according to the layout design, with BL connecting to the source terminal of the first transistor and BLB connecting to the source terminal of the second transistor. These complementary bitlines carry complementary voltage levels during memory operations, providing the enhanced sensing margin and improved immunity to floating body effects that characterize this memory cell design.

The process further includes forming a wordline connected to the conductive material in each layer of the first and second transistor regions. The wordline provides a common gate control for the first and second transistor regions in each layer. In FIG. 3o, a staircase wordline (WL) is formed using tungsten as the conductive material. The staircase configuration is achieved through multiple lithography patterning and etching steps. The wordline connects to the gate terminals of both the first and second transistors in each layer, thereby providing common gate control for the transistor pairs. The common wordline control provides simultaneous operation of both transistors in the 2T1C memory cell structure. This enables complementary access to both plates of the storage capacitor during memory operations. The resulting structure includes vertically stacked 2T1C memory cells that provide improved performance over other 1T1C designs, including better sensing margins, longer retention times, and greater resistance to both floating body effects and row-hammer attacks.

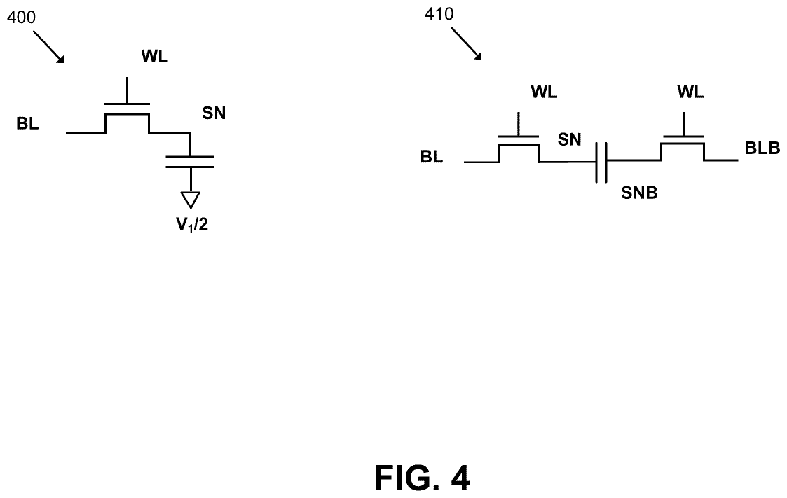

Example benefits of the present disclosure are highlighted and discussed in the following paragraphs and have been verified by SPICE simulation methodology. FIG. 4 depicts the schematics for a simulated 1T1C memory cell 400 and a 2T1C memory cell 410. The performance of the 2T1C memory cell is compared to that of the 1T1C memory cell. In the experiment, the following measurements are provided: a bitline capacitance of C_{BL}=40fF, a storage node capacitance of C_{SN}=4fF, a storage node voltage associated with a logical “1” bit of V₁=1.0V.

It should be noted that a single-sided write/read operation in a 1T1C cell aims to amplify the difference between BL which (once the hold transistor is enabled/opened) shares charge with SN vs. a reference BL kept at V₁/2 Volts. On the other hand, a double-sided write/read operation in a 2T1C cell aims to amplify the difference between BL which (once the hold transistor T1 is enabled/opened) shares charge with SN vs. BLB which (once the second transistor is enabled/opened) shares charge with SNB.

The results of the simulation show that the 2T1C configuration offers a 3X larger signal than the 1T1C configuration. Simulation results demonstrate that the 2T1C configuration provides a sensing signal approximately three times larger than the 1T1C configuration. These results prove the following features of the 2T1C configuration: faster sensing can be achieved; smaller storage capacitance can be adopted; and periphery area can be saved because the sense amplifier can be smaller, due to the larger differential signal.

The large sensing signal obtained by the 2T1C configuration can be considered an advantageous result. However, there are even higher benefits of adopting the 2T1C. To understand and highlight these benefits, the data loss due to leakage during a retention phase is studied, comparing again the 2T1C configuration with respect to a 1T1C configuration.

The results show that a 1T1C configuration is dramatically affected by leakage, which reduce the sensing differential. On the other hand, the 2T1C configuration is robust to leakage, thanks to the capacitive coupling that links the two sides of the capacitor and makes their voltage moving hand-in-hand therefore preserving the sensing differential intact. In order for a 2T1C configuration to lose differential voltage, both sides of the memory cell should have a leaky path, which is an exponentially lower probability event than having a single leaky path.

The above results demonstrate the following advantages. The refresh cycle of a 2T1C cell can be relaxed and made compared to the one of the 1T1C cell. The 2T1C cell is robust to defects (traps, dislocations etc.). It is rare that stochastic defects simultaneously affect both transistors of the 2T1C cell. A 2T1C cell is robust to floating body effects enhancing the dynamic leakage of a cell because floating body is related to holes generation by defecting transistor junctions and the probability to have random defects on both sides of the cells is exponentially lower that a single sided case 1T1C cell. A 2T1C cell is also robust to external attacks (like hammering attacks to wordlines and bitlines): this is because in order to force malicious data loss in a cell the attacker has to condition both sides of a 2T1C cell. A high and robust sensing differential allows to use smaller sense amplifiers, which enables to recover some of the chip area lost by the introduction of a second transistor in a 2T1C cell. Alternatively, designers may decide to pay this area penalty by not scaling the sense amplifiers area but gaining in sensing speed, therefore allowing the production of high performance DRAMs.

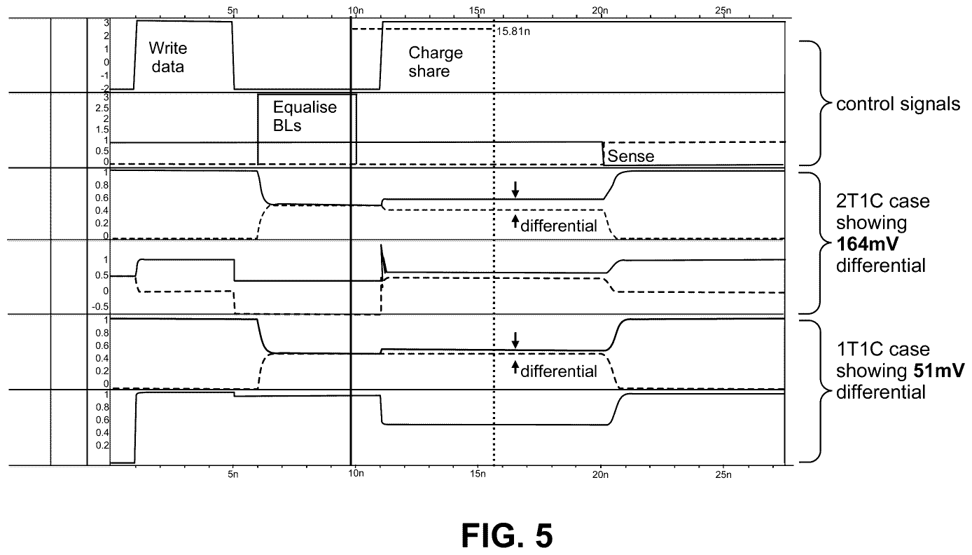

FIG. 5 illustrates a comparative analysis of signal behavior between a 2T1C memory cell as disclosed in the present disclosure and a 1T1C memory cell under ideal operating conditions. FIG. 5 presents timing diagrams showing various control signals and their corresponding voltage differentials during memory operations. The timing diagrams show several key control signals including a “write data” signal, a “charge share” signal, an “equalize bitlines (BLs)” signal, and a “sense” signal.

For the 2T1C configuration, the simulation demonstrates a large sensing margin with a differential voltage of 164 mV. This differential is achieved through double-sided write/read operations, where the voltage difference is measured between bitline (BL) sharing charge with the storage node (SN) and the complementary bitline (BLB) sharing charge with the complementary storage node (SNB). In contrast, the 1T1C configuration shows a smaller differential voltage of 51 mV. This configuration relies on single-sided write/read operations, where the voltage difference is measured between a bitline sharing charge with the storage node and a reference bitline maintained at V1/2 (half the voltage representing a logical “1”).

Under the ideal conditions (with bitline capacitance CBL=40fF, storage node capacitance CSN=4fF, and logical “1” voltage V1=1.0V), the 2T1C configuration achieves approximately three times larger sensing margin compared to the 1T1C design. This increased differential voltage leads to faster sensing capabilities, reduced storage capacitance requirements, potential for smaller sense amplifier circuits, and more reliable read operations.

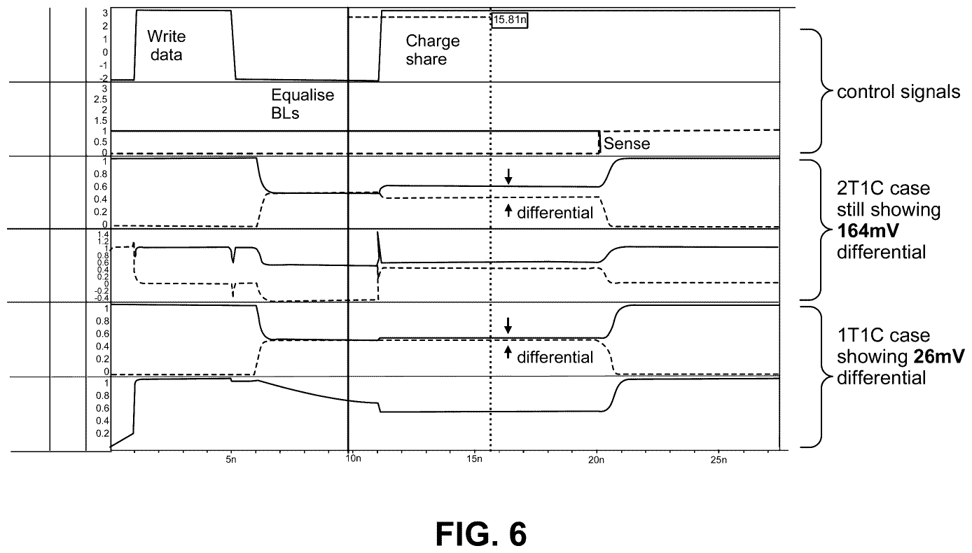

FIG. 6 illustrates a comparative analysis of signal behavior between a 2T1C memory cell and a 1T1C memory cell under leakage conditions. The figure presents timing diagrams showing various control signals and their corresponding voltage differentials during memory operations. The timing diagrams show several key control signals including a write data signal followed by a charge share signal, and an equalize bitlines (BLs) signal followed by a sense signal.

For the 2T1C configuration, the simulation demonstrates robustness to leakage, maintaining a differential voltage of 164 mV even under leakage conditions. This performance is achieved through the capacitive coupling between the two sides of the capacitor, which causes their voltages to move together when leakage occurs through one of the transistors, thereby preserving the sensing differential. In contrast, the 1T1C configuration shows significant degradation in performance under leakage conditions, with the differential voltage dropping to just 26 mV. This substantial reduction occurs because any charge lost during the hold period directly degrades the sensing margin in the single-sided architecture.

This comparison demonstrates a key advantage of the 2T1C design over the 1T1C structure: its inherent resistance to leakage effects. The 2T1C configuration maintains its full sensing margin unless both sides of the cell experience leakage simultaneously, which is statistically much less likely than single-sided leakage. This robust performance under leakage conditions provides longer refresh cycles, and better immunity to defects and floating body effects, and offers enhanced protection against external attacks such as row hammering.

According to some aspects, a sense amplifier is a circuit component that detects and amplifies small voltage differences between bitlines during memory read operations. In the context of the present disclosure, when reading data from a memory cell, the sense amplifier detects the voltage differential between the first bitline (BL) connected to the first transistor and the second bitline (BLB) connected to the second transistor. While the memory cell maintains a non-zero differential voltage between the first and second plates, it should be understood that in practical implementations, a sense amplifier's ability to detect and amplify this differential voltage depends on its internal offset voltage. This offset voltage, which results from statistical variability in threshold voltages between the two branches of the sense amplifier, effectively sets a minimum detectable voltage difference. However, through various technological and design optimizations, this offset voltage can be minimized, enabling the sense amplifier to detect and amplify increasingly smaller voltage differentials between the first and second plates of the storage capacitor.

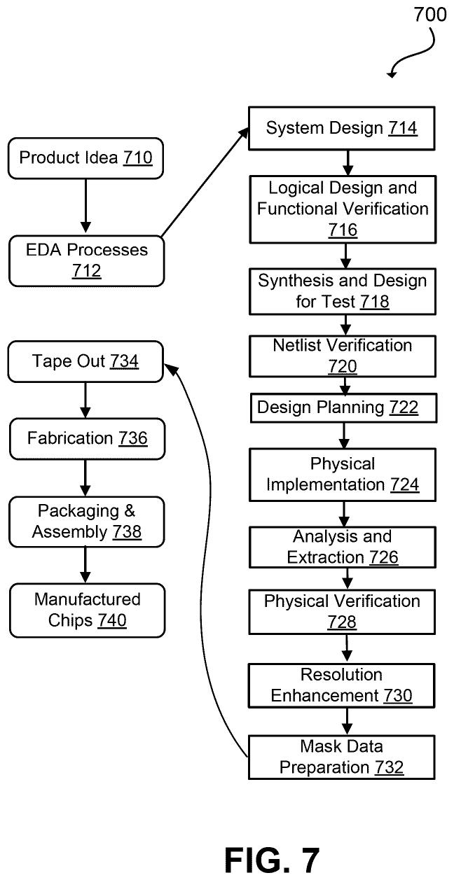

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE simulation methodology, which is used for detailed descriptions of circuits with many analog components. Descriptions at each level of representation are enabled for use by the corresponding systems of that layer (e.g., a formal verification system). A design process may use a sequence depicted in FIG. 7. The processes described may be enabled by EDA products (or EDA systems).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

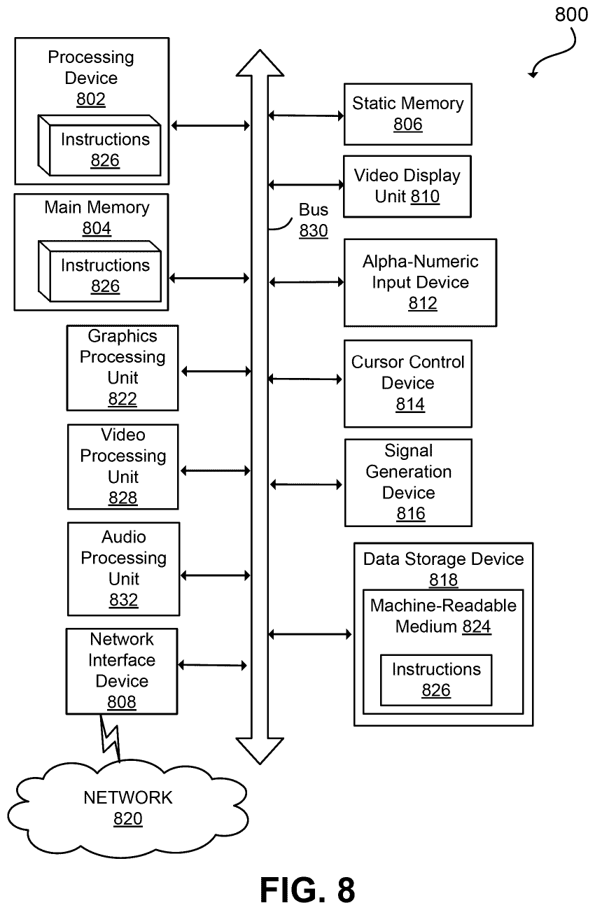

A storage subsystem of a computer system (such as computer system 800 of FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 870, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

As disclosed herein, and by way of example, a memory cell includes a capacitor, a first transistor and a second transistor. The capacitor has a first plate and a second plate. The first plate is adjacent to the second plate. The first transistor has a channel, a gate terminal, a source terminal, and a drain terminal wherein the gate terminal surrounds the channel, one side of the channel is connected to the source terminal, and another side of the channel is connected to the drain terminal. The second transistor has a channel, a gate terminal, a source terminal and a drain terminal, wherein the gate terminal surrounds the channel, one side of the channel is connected to the source terminal, and another side of the channel is connected to the drain terminal. The drain terminal of the first transistor is connected to the first plate of the capacitor. The gate terminal of the first transistor and the gate terminal of the second transistor are connected together. The drain terminal of the second transistor is connected to the second plate of the capacitor.

In some embodiments, a first bitline is connected to the source terminal of the first transistor, and a second bitline is connected to the source terminal of the second transistor. The first bitline and the second bitline are configured to carry complementary voltage levels. A wordline is connected to both the gate terminal of the first transistor and the gate terminal of the second transistor. The capacitor is configured to maintain a non-zero voltage differential between the first plate and the second plate in response to charge leakage through one of the first transistor or the second transistor.

The first plate is configured to store a first voltage level and the second plate is configured to store a second voltage level different from the first voltage level. The memory cell can maintain (or can be configured to maintain) a non-zero differential between the first plate and the second plate when charge leakage through one of the first transistor or second transistor causes a change in voltage level induced by capacitive coupling between the first plate and the second plate.

The charge leakage includes one of: source-to-drain leakage current through a channel of one of the first or second transistors; junction leakage current due to defects in one of the first or second transistors; leakage current due to floating body effects in one of the first or second transistors; and gate-induced drain leakage current in one of the first transistor or second transistor.

The capacitive coupling of the first plate and second plate provides protection against row-hammer attacks. Capacitive coupling between the first plate and the second plate of the capacitor causes a proportional change in voltage at both the first plate and the second plate in response to charge leakage through one of the first or second transistors.

The first transistor, the second transistor, and the capacitor are separated from each other by isolation regions.

In some aspects, a method of fabricating a three-dimensional memory device includes: providing alternating layers of a first semiconductor material and a second semiconductor material; defining first and second transistor regions in the alternating layers of the first and second semiconductor materials, wherein each of the first and second transistor regions are defined on opposite sides of the alternating layers; forming a gate on each layer of the first and second transistor regions, the gate including a conductive material; forming a capacitor region between each of the first and second transistor regions; connecting each of the first transistor regions with a first end of the capacitor region and connecting each of the second transistor regions with a second end of the capacitor region; forming bitlines comprising a first bitline connected to a source region in the first transistor region, and a second bitline connected to a source region in the second transistor region; and forming a wordline connected to the conductive material in each layer of the first and second transistor regions, wherein the wordline provides a common gate control for the first and second transistor regions in each layer.

The method further includes filling each layer of the first and second transistor regions with dielectric material, the dielectric material being deposited on at least a portion of the conductive material.

Forming the gate on each layer of the first and second transistor regions can include: removing the second semiconductor material from each of the first and second transistor regions to expose the first semiconductor material; and forming the gate on the exposed first semiconductor material.

Forming the capacitor region can include forming isolation regions between each of the first and second transistor regions and the capacitor region.

Forming the capacitor region can further include forming a sacrificial film in the capacitor region, and forming a capacitor film in the capacitor region after removing the sacrificial film, wherein the capacitor film comprises a first plate and a second plate separated by a dielectric material.

Forming the isolation regions can include forming isolation regions between different capacitor rows after forming the capacitor film, and filling the isolation regions with a dielectric material.

Connecting each of the first transistor regions with a first end of the capacitor region can include selectively etching first portions of the dielectric material to expose the first end of the capacitor region, and epitaxially growing a first region in the etched first portions of the dielectric material to connect a drain region of each of the first transistor regions to the exposed first end of the capacitor region.

Connecting each of the second transistor regions with a second end of the capacitor region can include selectively etching second portions of the dielectric material to expose the second end of the capacitor region, and epitaxially growing a second region in the etched second portions of the dielectric material to connect a drain region of each of the second transistor regions to the exposed second end of the capacitor region.

In some aspects, a three-dimensional memory device includes a plurality of memory cells, a first bitline, a second bitline, and a wordline. The plurality of memory cells are layered together forms a stack, having a first side and a second side. The first bitline is positioned along the first side of the stack. The second bitline is positioned along the second side of the stack. The wordline is connected to each layer of the stack. Each memory cell includes a capacitor region, a first transistor region, and a second transistor region. The capacitor region includes a capacitor having a first plate and a second plate. The first plate is adjacent to the second plate.

The first transistor region includes a first transistor having a channel, a gate terminal connected to a wordline, a source terminal connected to the first bitline, a drain terminal connected to the first plate of the capacitor, one side of the channel connected to the source terminal, and another side of the channel connected to the drain terminal. The second transistor region includes a second transistor having a channel, a gate terminal connected to the wordline, a source terminal connected to the second bitline, a drain terminal connected to the second plate of the capacitor, one side of the channel connected to the source terminal, and another side of the channel connected to the drain terminal. The first and second transistor regions are positioned on opposite sides of the capacitor region.

The disclosed configuration beneficially provides improved sensing margin, improved retention characteristics, and immunity to floating body effects and row-hammer attacks. The two-transistor-one-capacitor (2T1C) design may provide up to three times larger sensing margins compared to another one-transistor-one-capacitor (1T1C) circuit. configurations, while maintaining robust operation even in the presence of leakage currents.

Other aspects include components, devices, systems, improvements, methods, processes, applications, computer readable mediums, and other technologies related to any of the above.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A memory cell comprising:
a capacitor having a first plate and a second plate, wherein the first plate is adjacent to the second plate;
a first transistor having a channel, a gate terminal, a source terminal, and a drain terminal, wherein the gate terminal surrounds the channel, one side of the channel is connected to the source terminal, and another side of the channel is connected to the drain terminal; and
a second transistor having a channel, a gate terminal, a source terminal and a drain terminal, wherein the gate terminal surrounds the channel, one side of the channel is connected to the source terminal, and another side of the channel is connected to the drain terminal;
wherein the drain terminal of the first transistor is connected to the first plate of the capacitor, the gate terminal of the first transistor and the gate terminal of the second transistor are connected together, and the drain terminal of the second transistor is connected to the second plate of the capacitor.

2. The memory cell of claim 1, further comprising:
a first bitline connected to the source terminal of the first transistor; and
a second bitline connected to the source terminal of the second transistor.

3. The memory cell of claim 2, wherein the first bitline and the second bitline are configured to carry complementary voltage levels.

4. The memory cell of claim 1, further comprising a wordline connected to both the gate terminal of the first transistor and the gate terminal of the second transistor.

5. The memory cell of claim 1, wherein the capacitor is configured to maintain a non-zero voltage differential between the first plate and the second plate in response to charge leakage through one of the first transistor or the second transistor.

6. The memory cell of claim 1, wherein the first plate is configured to store a first voltage level and the second plate is configured to store a second voltage level different from the first voltage level, and further configured to maintain a non-zero differential between the first plate and the second plate when charge leakage through one of the first transistor or second transistor causes a change in voltage level induced by capacitive coupling between the first plate and the second plate.

7. The memory cell of claim 6, wherein the charge leakage comprises one of:
source-to-drain leakage current through a channel of one of the first or second transistors;
junction leakage current due to defects in one of the first or second transistors;
leakage current due to floating body effects in one of the first or second transistors; and
gate-induced drain leakage current in one of the first transistor or second transistor.

8. The memory cell of claim 6, wherein the capacitive coupling of the first plate and second plate provides protection against row-hammer attacks.

9. The memory cell of claim 1, wherein the first transistor, the second transistor, and the capacitor are separated from each other by isolation regions.

10. The memory cell of claim 1, wherein capacitive coupling between the first plate and the second plate of the capacitor causes a proportional change in voltage at both the first plate and the second plate in response to charge leakage through one of the first or second transistors.

11. A method of fabricating a three-dimensional memory device, comprising:
providing alternating layers of a first semiconductor material and a second semiconductor material;
defining first and second transistor regions in the alternating layers of the first and second semiconductor materials, wherein each of the first and second transistor regions are defined on opposite sides of the alternating layers;
forming a gate on each layer of the first and second transistor regions, the gate including a conductive material;
forming a capacitor region between each of the first and second transistor regions;
connecting each of the first transistor regions with a first end of the capacitor region and connecting each of the second transistor regions with a second end of the capacitor region;
forming bitlines comprising a first bitline connected to a source region in the first transistor region, and a second bitline connected to a source region in the second transistor region; and
forming a wordline connected to the conductive material in each layer of the first and second transistor regions, wherein the wordline provides a common gate control for the first and second transistor regions in each layer.

12. The method of claim 11, further comprising:
filling each layer of the first and second transistor regions with dielectric material, the dielectric material being deposited on at least a portion of the conductive material.

13. The method of claim 11, wherein forming the gate on each layer of the first and second transistor regions comprises:
removing the second semiconductor material from each of the first and second transistor regions to expose the first semiconductor material; and
forming the gate on the exposed first semiconductor material.

14. The method of claim 11, wherein forming the capacitor region further comprises:
forming isolation regions between each of the first and second transistor regions and the capacitor region.

15. The method of claim 14, wherein forming the capacitor region further comprises:
forming a sacrificial film in the capacitor region; and
forming a capacitor film in the capacitor region after removing the sacrificial film, wherein the capacitor film comprises a first plate and a second plate separated by a dielectric material.

16. The method of claim 14, wherein forming the isolation regions comprises:
forming isolation regions between different capacitor rows after forming the capacitor film; and
filling the isolation regions with a dielectric material.

17. The method of claim 11, wherein connecting each of the first transistor regions with a first end of the capacitor region comprises:
selectively etching first portions of the dielectric material to expose the first end of the capacitor region; and
epitaxially growing a first region in the etched first portions of the dielectric material to connect a drain region of each of the first transistor regions to the exposed first end of the capacitor region.

18. The method of claim 11, wherein connecting each of the second transistor regions with a second end of the capacitor region comprises:
selectively etching second portions of the dielectric material to expose the second end of the capacitor region; and
epitaxially growing a second region in the etched second portions of the dielectric material to connect a drain region of each of the second transistor regions to the exposed second end of the capacitor region.

19. A three-dimensional memory device, comprising:
a plurality of memory cells, the plurality of memory cells layered together forms a stack, having a first side and a second side;
a first bitline and a second bitline, the first bitline along the first side of the stack and the second bitline along the second side of the stack; and
a wordline connecting to each layer of the stack;
wherein each memory cell comprises:
a capacitor region comprising a capacitor having a first plate and a second plate, the first plate adjacent to the second plate;
a first transistor region comprising a first transistor having a channel, a gate terminal connected to a wordline, a source terminal connected to the first bitline, a drain terminal connected to the first plate of the capacitor, one side of the channel connected to the source terminal, and another side of the channel connected to the drain terminal; and
a second transistor region comprising a second transistor having a channel, a gate terminal connected to the wordline, a source terminal connected to the second bitline, a drain terminal connected to the second plate of the capacitor, one side of the channel connected to the source terminal, and another side of the channel connected to the drain terminal;
wherein the first and second transistor regions are positioned on opposite sides of the capacitor region.

20. The three-dimensional memory device of claim 19, wherein the capacitor is configured to maintain a non-zero voltage differential between the first and second plates in response to charge leakage through one of the first or second transistors.
